(19) United States
(12) Patent Application Publication
(10) Pub. No.: US 2024/0130068 A1
(43) Pub. Date: Apr. 18, 2024

(54) TECHNOLOGIES FOR A FLEXIBLE 3D POWER PLANE IN A CHASSIS

(71) Applicant: Intel Corporation, Santa Clara, CA (US)

(72) Inventors: Nan Wang, Shanghai (CN); Zhichao Z. Zhang, Shanghai (CN); Lihui Wu, Shanghai (CN); Jialiang Xu, Shanghai (CN); Xiaoguo Liang, Shanghai (CN); Bo Chen, Shanghai (CN); Haifeng Gong, Shanghai (CN)

(73) Assignee: Intel Corporation, Santa Clara, CA (US)

(21) Appl. No.: 18/399,565

(22) Filed: Dec. 28, 2023

(30) Foreign Application Priority Data
Nov. 22, 2023 (WO) PCT/CN2023/133190

(51) Int. Cl. H05K 7/14; H01R 12/79; H05K 1/02

(52) U.S. Cl. CPC H05K 7/1492; H01R 12/79; H05K 1/0213; H05K 7/1402; H05K 2201/0154; H05K 2201/10386

(57) ABSTRACT

Technologies for a flexible three-dimensional power plane in a chassis are disclosed. In one embodiment, a flexible ribbon cable is laid along a circuit board tray. The flexible ribbon cable is secured to the tray using power bosses. The power bosses connect to one or more conductors on the ribbon cable. When the circuit board is mounted on the circuit board tray, the power bosses extend through holes in the circuit board and mate with power clips on the surface of the circuit board tray. The ribbon cable, power bosses, and power clips can distribute power to various locations on the circuit board, without requiring large traces that take up space on the circuit board.

### CROSS-REFERENCE TO RELATED APPLICATIONS

This application claims the benefit under 35 U.S.C. § 119(a) of international patent application PCT/CN2023/133190, filed on Nov. 22, 2023, and entitled, “TECHNOLOGIES FOR A FLEXIBLE 3D POWER PLANE IN A CHASSIS.”

### BACKGROUND

There is an ever-increasing demand for increased compute power, such as for high-performance computing (HPC), artificial intelligence (AI), and other applications. Demand for increased compute power corresponds to an increase in power demand in a server. Additionally, modular sever design can complicate the issue of power delivery. To meet high power delivery, some options are more power layers on a circuit board, power cables to deliver power, and power bus bars on a motherboard.

Current approaches for power delivery have limitations. More power layers on a circuit board reduce the amount of area available to route signals and/or increase board complexity. Power cables increase system complexity regarding cable routing and management, take chassis space, and block airflow. Power bus bars are inflexible and takes space above a motherboard, which can lead to mechanical interference.

### BRIEF DESCRIPTION OF THE DRAWINGS

FIG. 1 is an isometric view of one embodiment of a system with a flexible power plane on a circuit board tray.

FIG. 2 is a top-down view of the system of FIG. 1.

FIG. 3 is an exploded view of the system of FIG. 1.

FIG. 4 is an isometric view of the circuit board and power board of the system of FIG. 1.

FIG. 5 is an isometric view of the flexible power plane and circuit board tray of the system of FIG. 1.

FIG. 6 is an isometric view of a power clip of the system of FIG. 1.

FIG. 7 is a cross-sectional view of the power clip of FIG. 6.

FIG. 8 is an isometric view of a power boss of the system of FIG. 1.

FIG. 9 is a cross-sectional view of the power boss of FIG. 8.

FIG. 10 is an isometric exploded view of the power boss of FIG. 8

FIG. 11 is a cross-sectional exploded view of the power boss of FIG. 8

FIG. 12 is a cross-sectional view of one embodiment of a power clip and power boss of the system of FIG. 1.

FIG. 13 is a cross-sectional view of one embodiment of a power clip and power boss of the system of FIG. 1.

FIG. 14 is an isometric view of one embodiment of a system with a flexible power plane on a circuit board tray.

FIG. 15 is an isometric view of one embodiment of a system with a flexible power plane on a circuit board tray.

FIG. 16 is an isometric exploded view of the system of FIG. 15.

FIG. 17 illustrates an embodiment of a block diagram for a compute system that may include the system of FIG. 1.

### DETAILED DESCRIPTION

In various embodiments disclosed herein, a compute device may include a circuit board mounted on a circuit board tray. A power plane is mounted on the circuit board tray. The power plane includes ribbon cables running along the surface of the circuit board tray, power bosses to deliver power up to the circuit board from the ribbon cables, and power clips on the circuit board to receive power from the power bosses. The ribbon cables may be flexible. The ribbon cables may carry two voltages (e.g., positive and ground) or one voltage.

Various embodiments described herein can provide any suitable combination of advantages. The ribbon cables can flexibly deliver power horizontally and vertically among several different system boards. The components, such as the ribbon cables, power bosses, and power clips, are modular, re-usable, and able to be standardized. The power plane under the circuit board can be low profile, mitigating or removing cable routing difficulties, mechanical interference, and/or airflow interference. The circuit board can be manufactured with fewer power traces, reducing the cost of the circuit board due to fewer power layers and ground layers and/or allowing for increased signal density and integrity on the circuit board due to few high current power layers.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

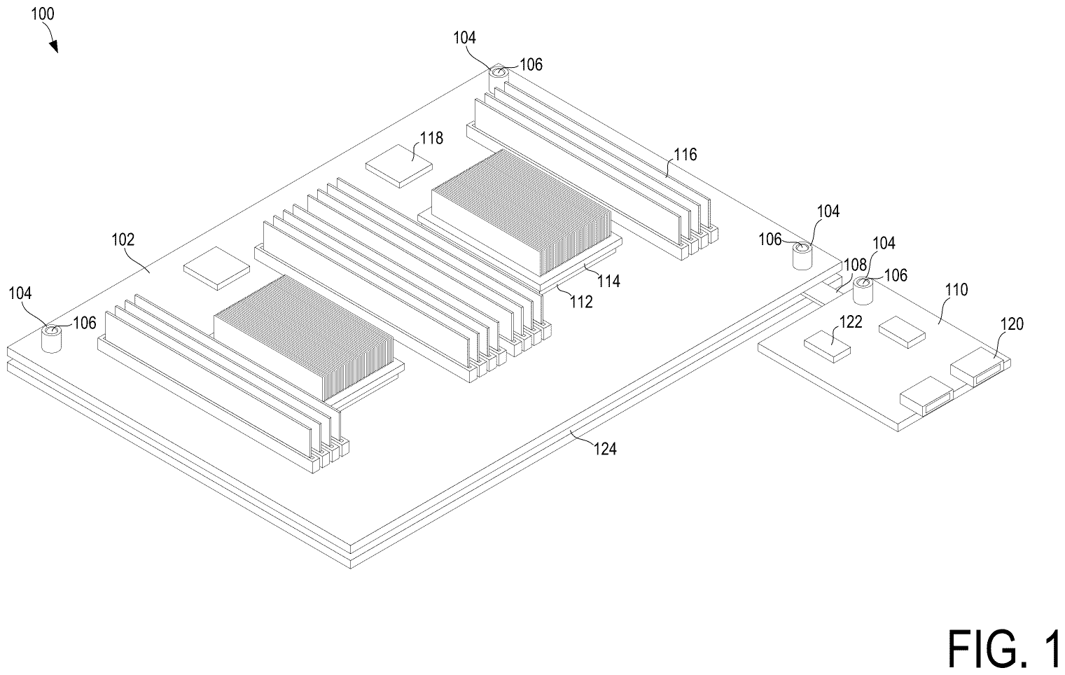

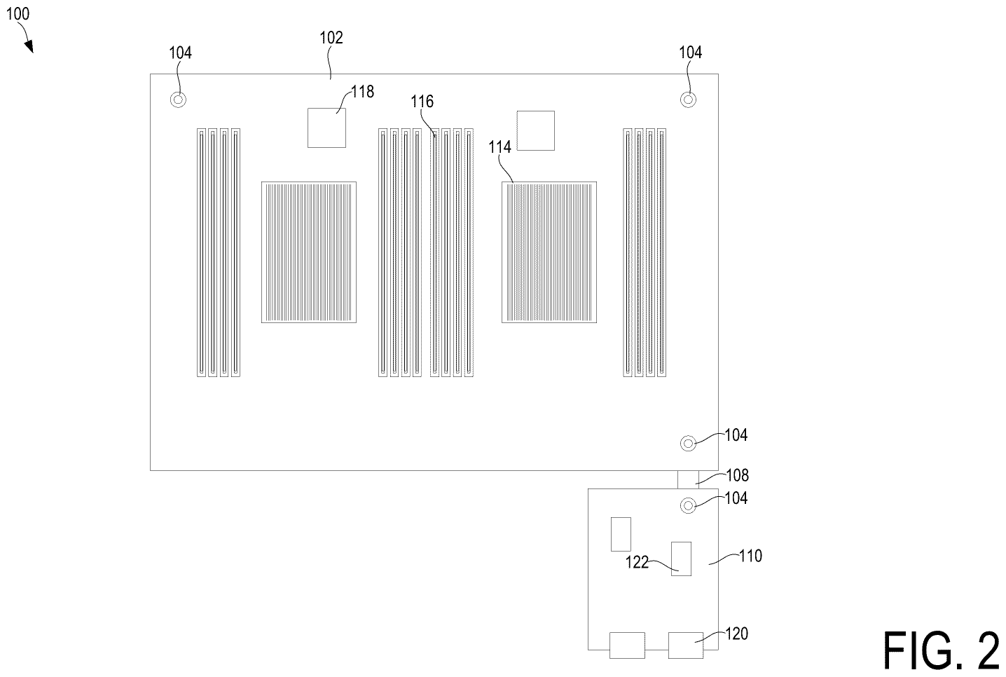

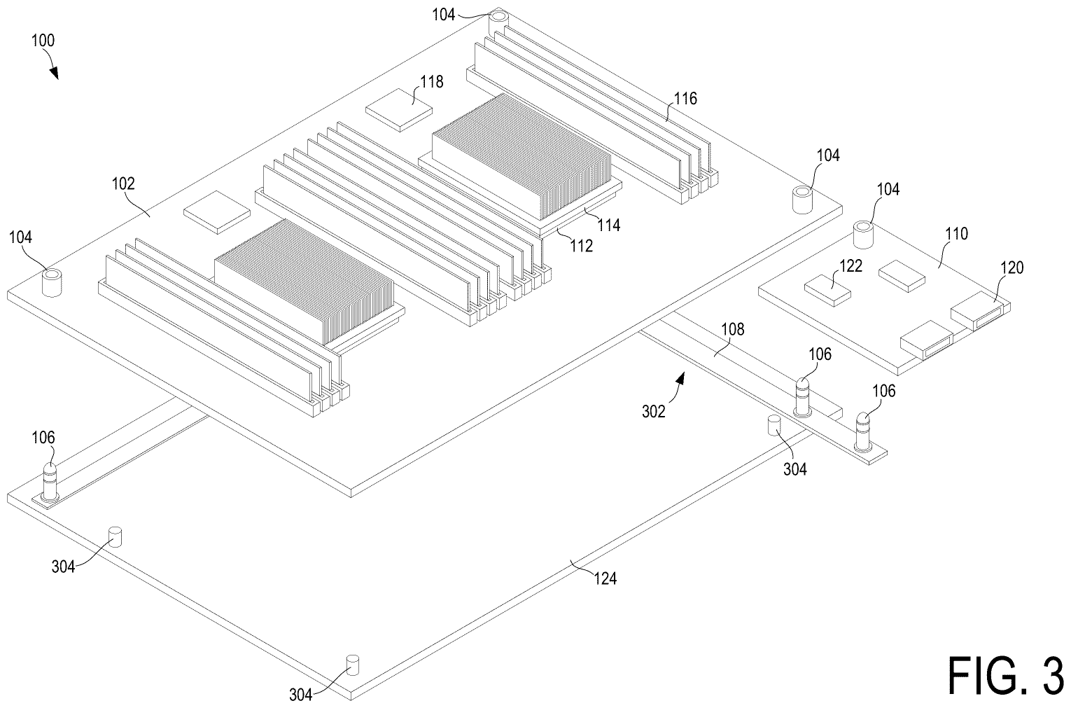

Referring now to FIGS. 1-3, in one embodiment, a system 100 includes a circuit board 102 mounted on a circuit board tray 124. FIG. 1 shows an isometric view of the system 100, FIG. 2 shows a top-down view of the system 100, and FIG. 3 shows an exploded view of the system 100, with the circuit board 102 separated from the circuit board tray 124. The system 100 includes a power plane 302 below the bottom side of the circuit board 102, including one or more ribbon cables 108. The power plane 302 distributes power from a power board 110 to various parts of the circuit board 102. Power bosses 106 mate with the circuit board tray 124 and the ribbon cables 108 to deliver the power vertically to the circuit board 102. The circuit board 102 includes power clips 104 that mate with the power bosses 106, as described in more detail below.

It should be appreciated that, as used herein, the “top side,” “bottom side,” etc., is an arbitrary designation used for clarity and does not denote a particular required orientation for manufacture or use. Although the illustrative embodiment described has the power plane 302, circuit board tray 124, etc., below the “bottom” side of the circuit board 102, in some embodiments, those components may additionally or alternatively be placed on the “top” side of the circuit board 102, depending on the orientation of various components.

The system 100 may be embodied as or be part of any suitable system, such as a server compute device, a desktop compute device, a rack compute device, a sled, a compute node, an edge compute node, etc. The circuit board 102 may be embodied as a motherboard, an input/output (I/O) board, a power distribution board, a storage board, a processor board, a communication board, and/or the like. The circuit board 102 may be embodied as a fiberglass board made of glass fibers and a resin, such as FR-4. In other embodiments, the circuit board 102 may be embodied as, e.g., a board with a glass core. The circuit board 102 may include one or more trace layers separated by one or more dielectric layers. The dielectric layers may be referred to as core or prepreg layers, as appropriate. The circuit board 102 may include any suitable number of trace layers separated by dielectric layers, such as 1-10. Each of the illustrative dielectric layers is a fiberglass board made of glass fibers and a resin, such as FR-4. In other embodiments, any suitable dielectric layers may be used. The thickness of each trace layer and/or dielectric layer can be any suitable thickness, such as 15 to 500 micrometers. The total thickness of the circuit board 102 may be any suitable thickness, such as 100 micrometers to 5 millimeters. The circuit board 102 can have any suitable length and width, such as 5-500 millimeters. Although shown as a rectangle, it should be appreciated that the circuit board 102 may be any suitable shape and may have protrusions, cutouts, etc., in order to accommodate, fit, or touch other components of a device. In the illustrative embodiment, the circuit board 102 and each layer are planar. In other embodiments, some or all of the circuit board 102 and layers may be non-planar.

The trace layers may include one or more traces made of copper or other conductor. The traces may carry power signals, carry high-speed input/output, establish ground planes, etc. The traces carrying power signals may connect to, e.g., the power clips 104. Traces for power signals may be able to carry large amounts of current, such as 1-100 amps. As such, some of the traces for power signals may have a relatively large area and/or thickness compared to other traces on the circuit board 102. For example, traces for power signals may have a width of, e.g., 1-20 millimeters. Each trace on the circuit board may have any suitable width, such as any width from 0.05-20 millimeters. In the illustrative embodiment, signal traces may have a width of 0.1-0.15 millimeters. Each trace on the circuit board may have any suitable height, such as any height from 5 micrometers to 40 micrometers. Vias may extend between trace layers through dielectric layers to connect traces on different trace layers.

As the ribbon cables 108 in the power plane 302 below the circuit board 102 distribute power to various places throughout the circuit board 102, the traces for power signals on the circuit board 102 itself can be reduced. As a result, the circuit board 102 may have a smaller form factor than it otherwise would without the power plane 302. Additionally or alternatively, the circuit board 102 may have fewer layers than it otherwise would without the power plane 302, as more of the circuit board 102 may be available to use to route high-speed signal traces.

In an illustrative embodiment, some of the traces may be embodied as a differential stripline that can carry high-speed signals. In other embodiments, there may be one high-speed signal trace that carries a signal, and there may be a ground plane or other ground traces near the signal trace. As used herein, a high-speed signal trace refers to a trace that connects two or more circuit components that will transmit and/or receive a signal on the high-speed signal trace at an analog frequency of 100 megahertz or higher. High-speed signal traces may be used for any suitable signal, such as a peripheral component interconnect express (PCIe) interconnect (e.g., a PCIe 6 interconnect), a memory interconnect (such as a DDR or GDDR memory interconnect), a compute express link (CXL) interconnect, a USB interconnect, a display interconnect, etc.

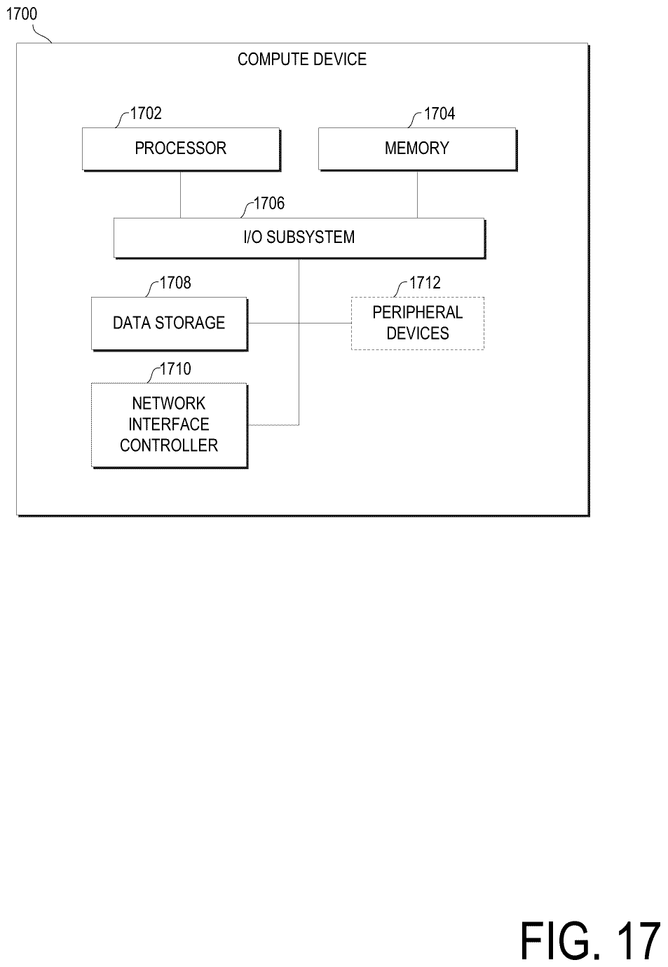

The circuit board 102 may include several other traces or connections not shown in the figures, such as connections between various integrated circuit components such as a processor circuit, a memory circuit, a display circuit, power components, circuit components, etc. For example, in one embodiment, the circuit board 102 supports one or more processors 112 and one or more memory modules 116. A heat sink 114 may be mounted on each of the processors 112. Additional components 118, such as other integrated circuit components, may be mounted on the circuit board 102 as well to perform various functions, as needed. In some embodiments, the circuit board 102 may interface with or form a part of, e.g., the processor 1702, system memory 1704, etc., described below in regard to FIG. 17. For example, the processor 112 may be embodied as the processor 1702, and/or the memory 116 may be embodied as the memory 1704.

In one embodiment, a power delivery board 110 delivers power to the circuit board 102 through the power plane 302, the ribbon cables 108, the power bosses 106, and the power clips 104. The power delivery board 110 may have sockets 120 to receive power cables, and the voltage can be routed on the power delivery board 110 to the power clip 104 on the power delivery board 110 and, from there, to the circuit board 102. The power delivery board 110 may be a similar material and include similar layers as the circuit board 102. The power delivery board 110 may include additional components 122, such as integrated circuit components, voltage regulators, capacitors, inductors, etc.

The circuit board tray 124 is configured to support the circuit board 102. The circuit board tray 124 may be embodied as, e.g., part of a metal chassis. The circuit board tray 124 may support stand-offs 304. The circuit board 102 is mounted on the stand-offs 304, establishing the circuit board 102 at a fixed distance away from the circuit board tray 124.

As shown in FIG. 3, the power bosses 106 are mounted on the circuit board tray 124, and the power clips 104 are mounted on the circuit board 102. When the circuit board 102 is mounted on the circuit board tray 124, the power bosses 106 mate with the power clips, as described in more detail below.

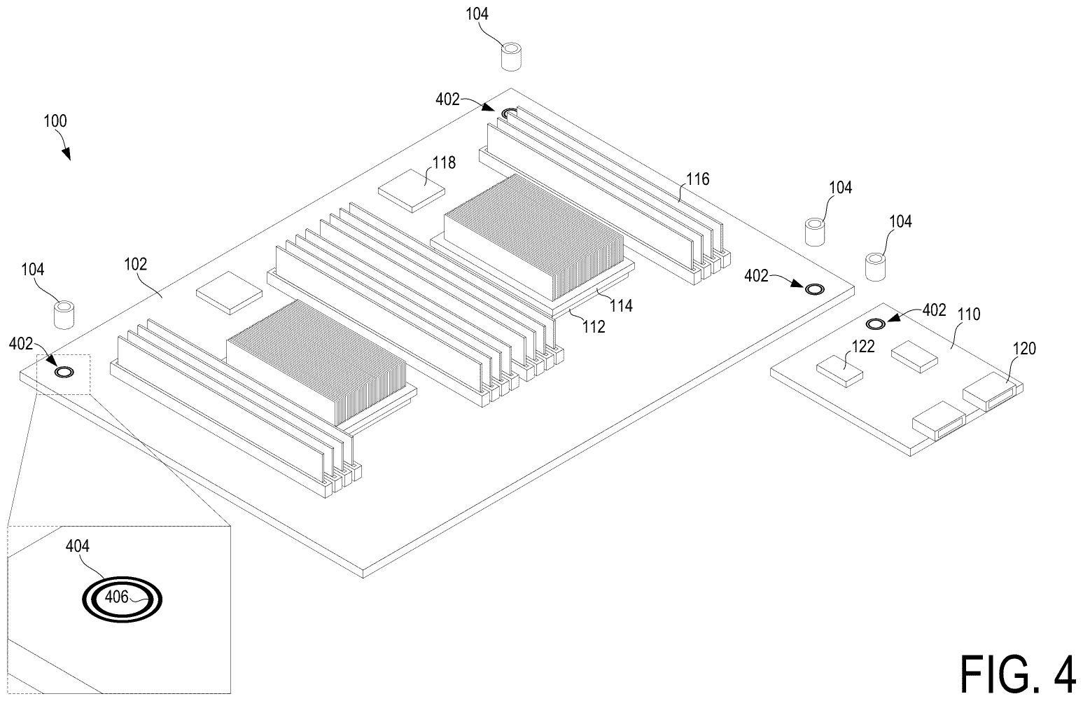

Referring now to FIG. 4, in one embodiment, the power clips 104 are mounted on concentric ring traces 404, 406 surrounding a hole 402 on the circuit board 102. When the power clips 104 are mounted on the circuit board 102, the concentric rings 404, 406 are connected to different voltages at the power clips 104. The concentric rings 404, 406 are connected to vias, traces, etc., that can carry the voltages to different parts of the circuit board 102. The power clips 104 may be secured to the circuit board 102 using, e.g., solder. A hole within the concentric rings 404, 406 may extend from a top surface of the circuit board 102 to the bottom surface of the circuit board 102. In some embodiments, the hole may be plated and connected to a conductor on the power boss 106. In the illustrative embodiment, the power clips 104 are installed on the top surface of the circuit board 102. In some embodiments, the power clips 104 may be installed on the bottom surface of the circuit board 102, between the circuit board 102 and the circuit board tray 124.

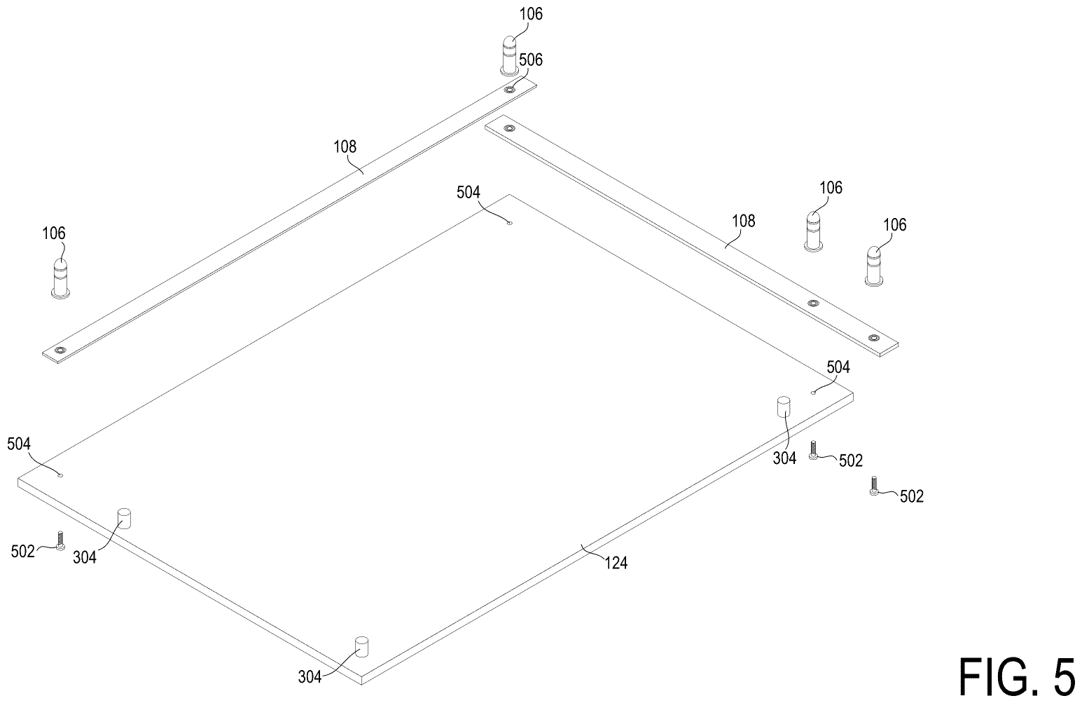

Referring now to FIG. 5, in one embodiment, an exploded view of the circuit board tray 124, power plane 302, ribbon cables 108, and power bosses 106 is shown. In the illustrative embodiment, screws 502 are inserted into holes 504 of the tray 124, through a hole 506 in the ribbon cable 108, and fastened to the power boss 106. In this manner, the screws 502 hold the power bosses 106 and the ribbon cables 108 in place. In some embodiments, a screw 502 can pass through two ribbon cables, allowing for a change in direction in the power distribution, as shown in the figure.

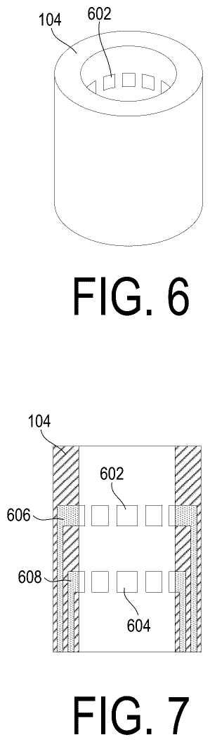

Referring now to FIGS. 6 and 7, in one embodiment, an isometric view of a power clip 104 is shown in FIG. 6, and a cross-sectional view of the power clip 104 is shown in FIG. 6. FIGS. 6 and 7 show pads 602 and pads 604, which connect to conductors on the power boss 106 at different voltage. Traces 606, 608 internal to the power clip 104 connect the pads 602, 604 to the concentric rings 404, 406 on the circuit board 102.

The body of the power clip 104 may be made of any suitable non-conductive material, such as plastic. The pads 602, 604 and traces 606, 608 may be made of any suitable material, such as copper, gold, nickel, aluminum, and/or a combination of those. The power clip 104 may have any suitable dimensions, such as a height of 1-15 millimeters, an outer diameter of 1-15 millimeters, and an inner diameter of 0.5-10 millimeters.

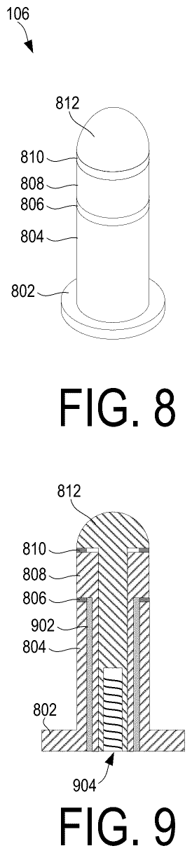

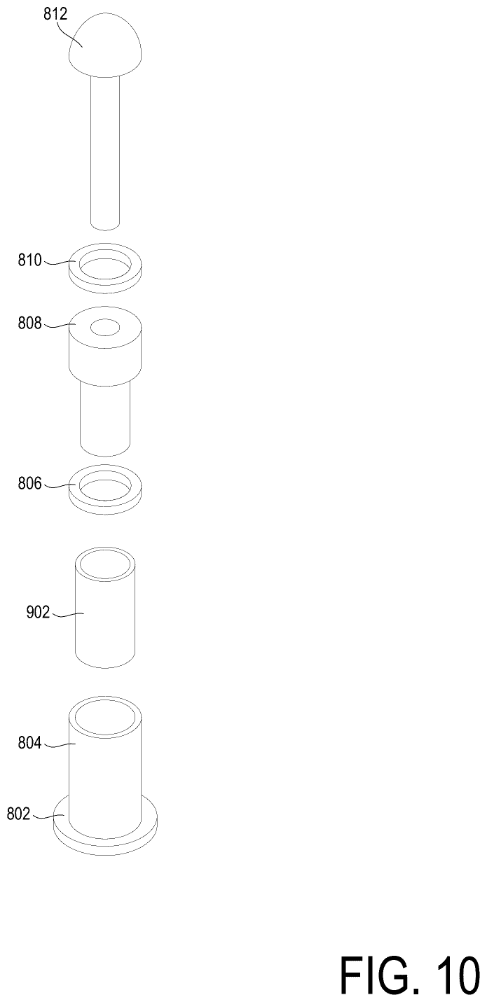

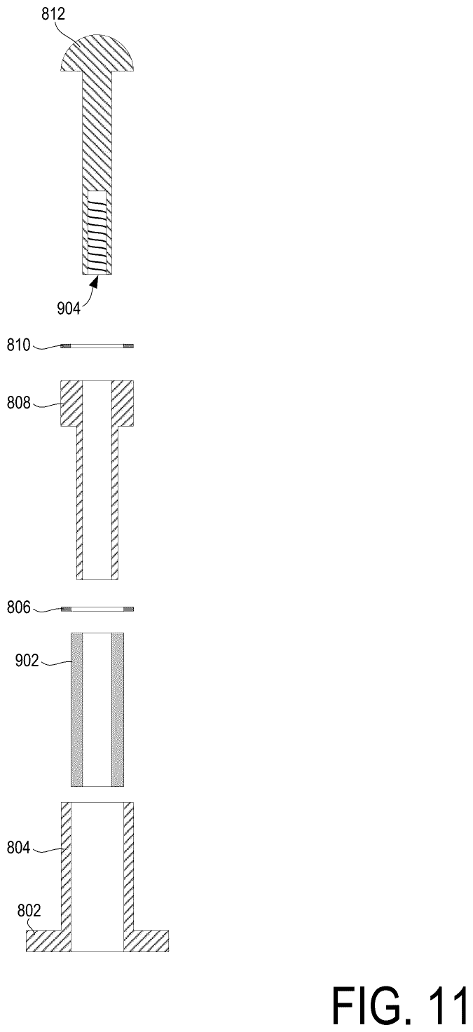

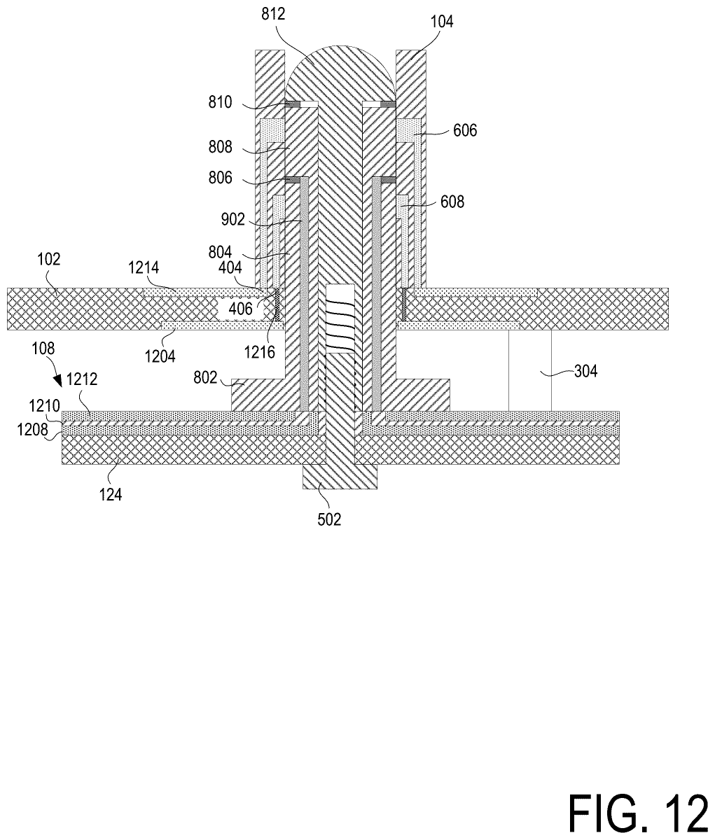

Referring now to FIGS. 8-11, in one embodiment, an isometric view of a power boss 106 is shown in FIG. 8, a cross-sectional view of the power boss 106 is shown in FIG. 9, an exploded isometric view of the power boss 106 is shown in FIG. 10, and an exploded cross-sectional view of the power boss 106 is shown in FIG. 11. The power boss 106 includes a flange 802, a lower conductor 804, and an upper conductor 808. In an illustrative embodiment, the flange 802 and the lower conductor 804 form one continuous component. The lower conductor 804 extends to the outer area of the bottom of the power boss 106, and the upper conductor 808 extends to an inner area of the bottom of the power boss 106, as shown in FIG. 9. In this manner, the lower conductor 804 can connect to a conductor at one voltage on the ribbon cable 108, and the upper conductor 808 can connect to a conductor at another voltage on the ribbon cable 108, as discussed below in regard to FIG. 12. A non-conducting insulating pipe 902 and an insulating washer 806 isolate the upper conductor 808 and the lower conductor 804. A locking pin 812 extends from the top of the power boss 106 towards the bottom, with a tapped hole 904 at the end. In use, a screw 502 mates with the tapped hole 904, securing the locking pin 812 and the rest of the power boss 106 in place. An insulator washer 810 may be positioned between the locking pin 812 and the upper conductor 808.

The power boss 106 may have any suitable dimensions, such as a height of 1-25 millimeters and a diameter of 0.5-10 millimeters. The upper conductor 808, lower conductor 804, and flange 802 may be made of any suitable material, such as copper, gold, nickel, aluminum, and/or a combination of those. The non-conducting insulating pipe 902 may be made of any suitable material, such as plastic. The washers 806, 810 may be made of any suitable material, such as plastic or rubber.

Referring now to FIG. 12, in one embodiment, a cross-sectional view shows the power boss 106 extending through the circuit board 102 and mating with the power clip 104. The ribbon cable 108 has two conductors, a bottom conductor 1208 and a top conductor 1212. The conductors 1208, 1212 are separated by an insulator 1210. The conductors 1208, 1212 may be any suitable material, such as copper. The insulator 1210 may be any suitable material, such as polyimide. In some embodiments, another insulator may be present below the bottom conductor 1208 and/or above the top conductor 1212 to further isolate the conductors 1208, 1212 from accidental or incidental contact. Additionally or alternatively, in some embodiments, the ribbon cable 108 may be embodied as a flexible printed circuit board.

In the illustrative embodiment, the bottom conductor 1208 of the ribbon cable 108 is connected to the upper conductor 808 of the power boss 106, and the top conductor 1212 of the ribbon cable 108 is connected to the lower conductor 804 of the power boss. The upper conductor 808 of the power boss 106 is connected to the trace 606 of the power clip 104. The lower conductor 804 of the power boss 106 is connected to the trace 608 of the power clip. The trace 606 of the power clip 104 is connected to the ring 404 on the circuit board 102. The ring 404 may be connected to a trace 1214, as shown in FIG. 12. The trace 608 of the power clip 104 is connected to the ring 406 on the circuit board 102. The ring 406 may be connected to a via 1216 and a trace 1204 on a different layer of the circuit board 102, as shown in FIG. 12. Together, the ribbon cable 108, power boss 106, and power clip 104 connect the top conductor 1212 of the ribbon cable 108 to the trace 1204 on the circuit board 102 and connect the bottom conductor 1208 of the ribbon cable 108 to the trace 1214 on the circuit board 102.

The ribbon cable 108 and the conductors 1208, 1212 may have any suitable dimensions. For example, in one embodiment, the conductors 1208, 1212 have a thickness of about 140 micrometers each, with a width of 30 millimeters and a length of up to 300 millimeters. Such a thickness of, e.g., copper may be referred to as four ounces or four ounces of copper per square foot. Such a conductor 1208, 1212 would have a resistance of about 1 milliohm. With a width increased up to 60 millimeters and a length of 150 millimeters, the resistance would be only 0.25 milliohm. In general, the conductors 1208, 1212 may have any suitable thickness, such as 10-500 micrometers, and any suitable width, such as 5-150 millimeters. It should be appreciated that relatively wide, thin ribbon cables can reduce the impediment to airflow while still providing low resistance. It should be appreciated that, in the illustrative embodiment, the ribbon cables 108 are flexible, making layout of the ribbon cables 108 easier. In some embodiments, the ribbon cables 108 may be secured to the tray 124, such as with an adhesive. In other embodiments, the ribbon cables 108 may be held in place by gravity and/or the screws 502 securing the power bosses 106.

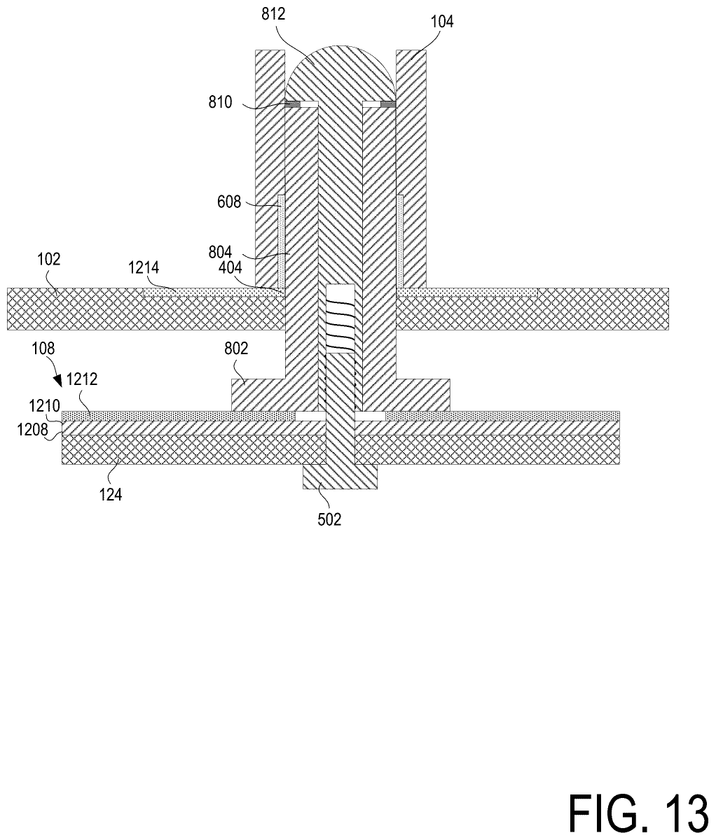

Referring now to FIG. 13, in some embodiments, a power boss 106 may only carry a single voltage. Such a power boss 106 may be formed from a flange 802, a conductor 804, a washer 810, and a pin 812. The power boss 106 may mate with a ribbon cable 108 with only a top conductor 1212 and mate with a power clip 104 with only one trace 608. The power clip 104 with one trace 608 may mate with one circle 404 on the circuit board 102. Such an embodiment may be used to provide one voltage at one location on the circuit board 102. Another power boss 106 at another location may provide a different voltage to the circuit board 102. Such an approach may allow for more flexibility in distributing voltage to the circuit board 102. Additionally, such an approach may make it simpler to join two ribbon cables 108 at a junction, as shown in FIG. 5.

In an illustrative embodiment, the flexible power plane 302 is installed without any input power, and all components are locked into the correct position by screws 502 and fasteners connecting the circuit board 102 to the stand-offs 304. Once every component is installed with no power-ground short, then system 100 can be powered on.

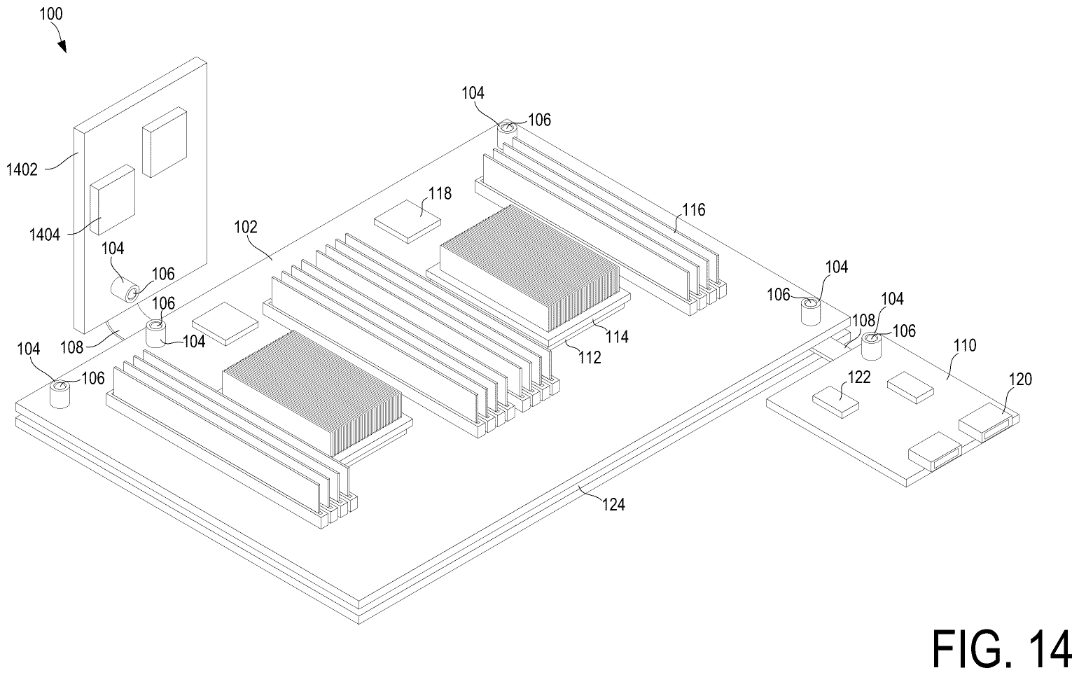

Referring now to FIG. 14, in one embodiment, the power plane 302 and ribbon cables 108 may be used to distribute power to vertical power boards 1402. The vertical board 1402 may include one or more integrated circuit components 1404. The vertical board 1402 may be used for, e.g., storage backplane or I/O riser installation. The ribbon cable 108 can be extended to the vertical board 1402 and mate with a power clip 104 using a power boss 106.

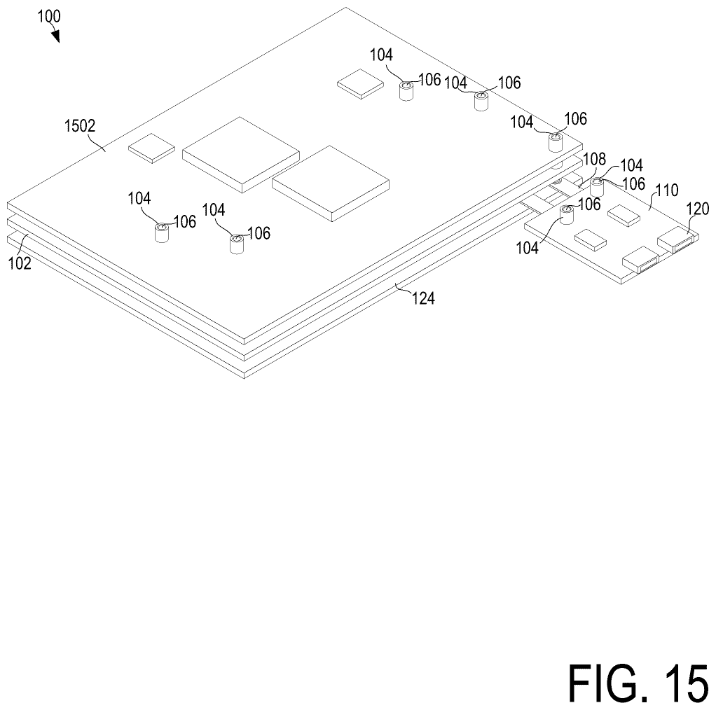

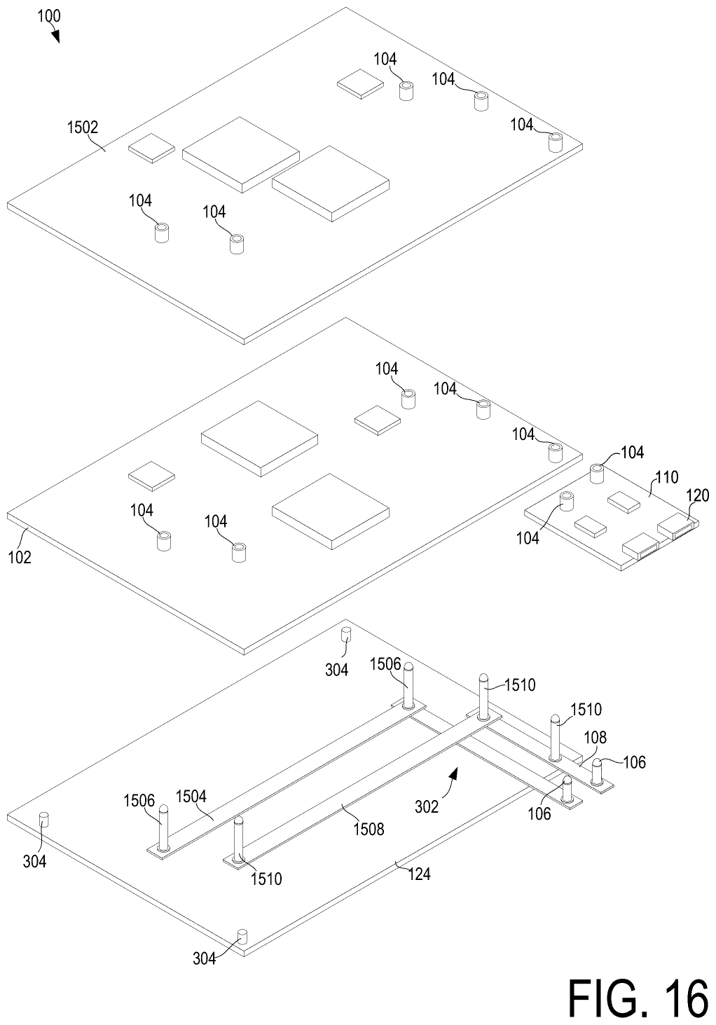

Referring now to FIGS. 15 and 16, in one embodiment, the power plane 302 and ribbon cables 108 may be used to distribute power to vertically-stacked or mezzanine boards 1502. FIG. 15 shows a stack-up board 1502 on top of the circuit board 102, and FIG. 16 shows an exploded view of the stack-up board 1502 and the circuit board 102. The power plane 302 may include ribbon cables 1504 and power bosses 1506 at a first voltage and ribbon cables 1508 and power bosses 1510 at a second voltage. The power bosses 1506, 1510 carry a single voltage, similar to the power boss 106 shown in FIG. 13. To reach the stack-up board 1502, the power bosses 1506, 1510 may be longer than the power bosses 106 used to connect to one circuit board 102.

It should be appreciated that the power distribution system described above can provide several advantages. The flexible ribbon cables 108 can be plugged into vertical boards, as shown in FIG. 14. The components, such as the ribbon cables 108, power bosses 106, and power clips 104, are re-usable and standardized, which can be flexibly used to support different types of server design, leveraging the whole tray space. Using the power plane 302 below the circuit board 102 can reduce the cost of the circuit board 102 by requiring fewer power layers and ground layers in the circuit board 102 design. Reducing the power layers and ground layers can also improve signal integrity in the circuit board 102 and reduce design complexity with fewer high current power layers. The ribbon cables 108 take very little chassis space, resolving or mitigating the issues caused by power cable and bus bar solutions, such as cable routing, space taking, mechanical interference, airflow blocking, etc.

Referring now to FIG. 17, in one embodiment, a compute device 1700 is shown. The compute device 1700 may be embodied as any type of compute device. For example, the compute device 1700 may be embodied as or otherwise be included in, without limitation, a server computer, an embedded computing system, a System-on-a-Chip (SoC), a multiprocessor system, a processor-based system, a consumer electronic device, a smartphone, a cellular phone, a desktop computer, a tablet computer, a notebook computer, a laptop computer, a network device, a router, a switch, a networked computer, a wearable computer, a handset, a messaging device, a camera device, and/or any other compute device. In some embodiments, the compute device 1700 may be located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that hosts companies applications and data), and an edge data center (e.g., a data center, typically having a smaller footprint than other data center types, located close to the geographic area that it serves).

The illustrative compute device 1700 includes a processor 1702, a memory 1704, an input/output (I/O) subsystem 1706, data storage 1708, communication circuitry 1710, a display 1712, and one or more peripheral devices 1714. The compute device 1700 may include the system 100, the circuit board 102, etc. For example, a component such as the processor 1702, the memory 1704, the data storage 1708, the communication circuitry 1710, the display 1712, etc., may include or otherwise be embodied as the system 100, the circuit board 102, the processor 112, the memory 116, etc. In some embodiments, one or more of the illustrative components of the compute device 1700 may be incorporated in, or otherwise form a portion of, another component. For example, the memory 1704, or portions thereof, may be incorporated in the processor 1702 in some embodiments. In some embodiments, one or more of the illustrative components may be physically separated from another component.

The processor 1702 may be embodied as any type of processor capable of performing the functions described herein. For example, the processor 1702 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 1704 may be embodied as any type of volatile or non-volatile memory or data storage capable of performing the functions described herein. In operation, the memory 1704 may store various data and software used during operation of the compute device 1700 such as operating systems, applications, programs, libraries, and drivers. The memory 1704 is communicatively coupled to the processor 1702 via the I/O subsystem 1706, which may be embodied as circuitry and/or components to facilitate input/output operations with the processor 1702, the memory 1704, and other components of the compute device 1700. For example, the I/O subsystem 1706 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. The I/O subsystem 1706 may connect various internal and external components of the compute device 1700 to each other with use of any suitable connector, interconnect, bus, protocol, etc., such as an SoC fabric, PCIe®, USB2, USB3, USB4, NVMe®, Thunderbolt®, and/or the like. In some embodiments, the I/O subsystem 1706 may form a portion of a system-on-a-chip (SoC) and be incorporated, along with the processor 1702, the memory 1704, and other components of the compute device 1700 on a single integrated circuit chip.

The data storage 1708 may be embodied as any type of device or devices configured for the short-term or long-term storage of data. For example, the data storage 1708 may include any one or more memory devices and circuits, memory cards, hard disk drives, solid-state drives, or other data storage devices.

The communication circuit 1710 may be embodied as any type of interface capable of interfacing the compute device 1700 with other compute devices, such as over one or more wired or wireless connections. In some embodiments, the communication circuit 1710 may be capable of interfacing with any appropriate cable type, such as an electrical cable or an optical cable. The communication circuit 1710 may be configured to use any one or more communication technology and associated protocols (e.g., Ethernet, Bluetooth®, Wi-Fi®, WiMAX, near field communication (NFC), etc.). The communication circuit 1710 may be located on silicon separate from the processor 1702, or the communication circuit 1710 may be included in a multi-chip package with the processor 1702, or even on the same die as the processor 1702. The communication circuit 1710 may be embodied as one or more add-in-boards, daughtercards, network interface cards, controller chips, chipsets, specialized components such as a field-programmable gate array (FPGA) or application-specific integrated circuit (ASIC), or other devices that may be used by the compute device 1700 to connect with another compute device. In some embodiments, communication circuit 1710 may be embodied as part of a system-on-a-chip (SoC) that includes one or more processors or included on a multichip package that also contains one or more processors. In some embodiments, the communication circuit 1710 may include a local processor (not shown) and/or a local memory (not shown) that are both local to the communication circuit 1710. In such embodiments, the local processor of the communication circuit 1710 may be capable of performing one or more of the functions of the processor 1702 described herein. Additionally or alternatively, in such embodiments, the local memory of the communication circuit 1710 may be integrated into one or more components of the compute device 1700 at the board level, socket level, chip level, and/or other levels.

The display 1712 may be embodied as any type of display on which information may be displayed to a user of the compute device 1700, such as a touchscreen display, a liquid crystal display (LCD), a thin film transistor LCD (TFT-LCD), a light-emitting diode (LED) display, an organic light-emitting diode (OLED) display, a cathode ray tube (CRT) display, a plasma display, an image projector (e.g., 2D or 3D), a laser projector, a heads-up display, and/or other display technology. The display 1712 may have any suitable resolution, such as 7680×4320, 3840×2160, 1920×1200, 1920×1080, etc.

In some embodiments, the compute device 1700 may include other or additional components, such as those commonly found in a compute device. For example, the compute device 1700 may also have peripheral devices 1714, such as a keyboard, a mouse, a speaker, an external storage device, etc. In some embodiments, the compute device 1700 may be connected to a dock that can interface with various devices, including peripheral devices 1714.

### Examples

Illustrative examples of the technologies disclosed herein are provided below. An embodiment of the technologies may include any one or more, and any combination of, the examples described below.

Example 1 includes a system comprising a circuit board; a tray disposed below the circuit board; a power plane adjacent the tray; one or more power clips disposed on a surface of the circuit board; and one or more power bosses extending from the power plane, through the circuit board, to a corresponding one of the one or more power clips.

Example 2 includes the subject matter of Example 1, and wherein the power plane comprises one or more flexible ribbon cables.

Example 3 includes the subject matter of any of Examples 1 and 2, and wherein individual flexible ribbon cables of the one or more flexible ribbon cables comprise a copper ribbon disposed on a flexible, non-conductive substrate.

Example 4 includes the subject matter of any of Examples 1-3, and wherein the substrate is polyimide.

Example 5 includes the subject matter of any of Examples 1-4, and wherein individual flexible ribbon cables of the one or more flexible ribbon cables are flexible printed circuit boards.

Example 6 includes the subject matter of any of Examples 1-5, and further including a power delivery board; one or more power clips disposed on a surface of the power delivery board; and one or more power bosses extending from the power plane, through the power delivery board, to a corresponding one of the one or more power clips of the power delivery board.

Example 7 includes the subject matter of any of Examples 1-6, and further including a second circuit board oriented perpendicular to the circuit board; one or more power clips disposed on a surface of the second circuit board; and one or more power bosses extending from the power plane, through the second circuit board, to a corresponding one of the one or more power clips of the second circuit board.

Example 8 includes the subject matter of any of Examples 1-7, and further including a second circuit board positioned above the circuit board; and one or more power clips disposed on a surface of the second circuit board, wherein the one or more power bosses extend from the power plane, through the circuit board, and through the second circuit board, to a corresponding one of the one or more power clips of the second circuit board.

Example 9 includes the subject matter of any of Examples 1-8, and wherein the one or more power bosses comprises an upper conductor to provide a first voltage and a lower conductor to provide a second voltage different from the first voltage.

Example 10 includes the subject matter of any of Examples 1-9, and wherein the one or more power bosses are configured to provide only one voltage each.

Example 11 includes a system comprising a circuit board, wherein two concentric rings are disposed on a surface of the circuit board; a power clip disposed on the surface of the circuit board, wherein the power clip comprises a first trace connected to a first ring of the two concentric rings and a second trace connected to a second ring of the two concentric rings; a power boss mated with the power clip, wherein the power boss comprises a first conductor connected to the first trace and a second conductor connected to the second trace; and a ribbon cable, wherein the ribbon cable comprises a first conductor connected to the first conductor of the power boss and a second conductor connected to the second conductor of the power boss.

Example 12 includes the subject matter of Example 11, and wherein the ribbon cable is flexible.

Example 13 includes the subject matter of any of Examples 11 and 12, and wherein the ribbon cable comprises a copper ribbon disposed on a flexible, non-conductive substrate.

Example 14 includes the subject matter of any of Examples 11-13, and wherein the substrate is polyimide.

Example 15 includes the subject matter of any of Examples 11-14, and wherein the ribbon cable is a flexible printed circuit board.

Example 16 includes the subject matter of any of Examples 11-15, and further including a power delivery board; one or more power clips disposed on a surface of the power delivery board; and one or more power bosses extending from the ribbon cable, through the power delivery board, to a corresponding one of the one or more power clips of the power delivery board.

Example 17 includes the subject matter of any of Examples 11-16, and further including a second circuit board oriented perpendicular to the circuit board; one or more power clips disposed on a surface of the second circuit board; and one or more power bosses extending from the ribbon cable, through the second circuit board, to a corresponding one of the one or more power clips of the second circuit board.

Example 18 includes the subject matter of any of Examples 11-17, and further including a second circuit board positioned above the circuit board; and one or more power clips disposed on a surface of the second circuit board, wherein the power boss extends from the ribbon cable, through the circuit board, and through the second circuit board, to a corresponding one of the one or more power clips of the second circuit board.

Example 19 includes the subject matter of any of Examples 11-18, and wherein the power boss comprises an upper conductor to provide a first voltage and a lower conductor to provide a second voltage different from the first voltage.

Example 20 includes the subject matter of any of Examples 11-19, and wherein the power boss is configured to provide only one voltage.

Example 21 includes a system comprising a circuit board; a tray disposed below the circuit board; and means for distributing power along the tray and to the circuit board.

Example 22 includes the subject matter of Example 21, and wherein the means for distributing power along the tray and to the circuit board comprises one or more flexible ribbon cables.

Example 23 includes the subject matter of any of Examples 21 and 22, and wherein individual flexible ribbon cables of the one or more flexible ribbon cables comprise a copper ribbon disposed on a flexible, non-conductive substrate.

Example 24 includes the subject matter of any of Examples 21-23, and wherein the substrate is polyimide.

Example 25 includes the subject matter of any of Examples 21-24, and wherein individual flexible ribbon cables of the one or more flexible ribbon cables are flexible printed circuit boards.

Example 26 includes the subject matter of any of Examples 21-25, and further including a power delivery board; and means for distributing power from the power delivery board, along the tray, and to the circuit board.

Example 27 includes the subject matter of any of Examples 21-26, and further including a second circuit board oriented perpendicular to the circuit board; and means for distributing power along the tray and to the second circuit board.

Example 28 includes the subject matter of any of Examples 21-27, and further including a second circuit board positioned above the circuit board; and means for distributing power along the tray, through the circuit board, and to the circuit board.

Example 29 includes a method comprising laying out a power plane on a circuit board tray; connecting one or more power bosses to the power plane on the circuit board tray; and mounting a circuit board on the circuit board tray, wherein mounting the circuit board comprises aligning one or more power clips on the circuit board with the one or more power bosses.

Example 30 includes the subject matter of Example 29, and further including mounting a second circuit board perpendicular to the circuit board; and connecting one or more power bosses from the power plane to one or more power clips on the second circuit board.

Example 31 includes the subject matter of any of Examples 29 and 30, and further including mounting a second circuit board on top of the circuit board; wherein mounting the second circuit board comprises aligning one or more power clips on the second circuit board with the one or more power bosses.

1. A system comprising:
a circuit board;
a tray disposed below the circuit board;
a power plane adjacent the tray;
one or more power clips disposed on a surface of the circuit board; and
one or more power bosses extending from the power plane, through the circuit board, to a corresponding one of the one or more power clips.

2. The system of claim 1, wherein the power plane comprises one or more flexible ribbon cables.

3. The system of claim 2, wherein individual flexible ribbon cables of the one or more flexible ribbon cables comprise a copper ribbon disposed on a flexible, non-conductive substrate.

4. The system of claim 3, wherein the substrate is polyimide.

5. The system of claim 2, wherein individual flexible ribbon cables of the one or more flexible ribbon cables are flexible printed circuit boards.

6. The system of claim 1, further comprising:
a power delivery board;
one or more power clips disposed on a surface of the power delivery board; and
one or more power bosses extending from the power plane, through the power delivery board, to a corresponding one of the one or more power clips of the power delivery board.

7. The system of claim 1, further comprising:
a second circuit board oriented perpendicular to the circuit board;
one or more power clips disposed on a surface of the second circuit board; and
one or more power bosses extending from the power plane, through the second circuit board, to a corresponding one of the one or more power clips of the second circuit board.

8. The system of claim 1, further comprising:
a second circuit board positioned above the circuit board; and
one or more power clips disposed on a surface of the second circuit board,
wherein the one or more power bosses extend from the power plane, through the circuit board, and through the second circuit board, to a corresponding one of the one or more power clips of the second circuit board.

9. The system of claim 1, wherein the one or more power bosses comprises an upper conductor to provide a first voltage and a lower conductor to provide a second voltage different from the first voltage.

10. The system of claim 1, wherein the one or more power bosses are configured to provide only one voltage each.

11. A system comprising:
a circuit board, wherein two concentric rings are disposed on a surface of the circuit board;
a power clip disposed on the surface of the circuit board, wherein the power clip comprises a first trace connected to a first ring of the two concentric rings and a second trace connected to a second ring of the two concentric rings;
a power boss mated with the power clip, wherein the power boss comprises a first conductor connected to the first trace and a second conductor connected to the second trace; and
a ribbon cable, wherein the ribbon cable comprises a first conductor connected to the first conductor of the power boss and a second conductor connected to the second conductor of the power boss.

12. The system of claim 11, wherein the ribbon cable is flexible.

13. The system of claim 11, further comprising:
a power delivery board;
one or more power clips disposed on a surface of the power delivery board; and
one or more power bosses extending from the ribbon cable, through the power delivery board, to a corresponding one of the one or more power clips of the power delivery board.

14. The system of claim 11, further comprising:
a second circuit board oriented perpendicular to the circuit board;
one or more power clips disposed on a surface of the second circuit board; and
one or more power bosses extending from the ribbon cable, through the second circuit board, to a corresponding one of the one or more power clips of the second circuit board.

15. The system of claim 11, further comprising:
a second circuit board positioned above the circuit board; and
one or more power clips disposed on a surface of the second circuit board,
wherein the power boss extends from the ribbon cable, through the circuit board, and through the second circuit board, to a corresponding one of the one or more power clips of the second circuit board.

16. A system comprising:
a circuit board;
a tray disposed below the circuit board; and
means for distributing power along the tray and to the circuit board.

17. The system of claim 16, wherein the means for distributing power along the tray and to the circuit board comprises one or more flexible ribbon cables.

18. The system of claim 16, further comprising:
a power delivery board; and
means for distributing power from the power delivery board, along the tray, and to the circuit board.

19. The system of claim 16, further comprising:
a second circuit board oriented perpendicular to the circuit board; and
means for distributing power along the tray and to the second circuit board.

20. The system of claim 16, further comprising:
a second circuit board positioned above the circuit board; and
means for distributing power along the tray, through the circuit board, and to the circuit board.
